(19) United States
(12) Patent Application Publication
(10) Pub. No.: US 2015/0063393 A1
(43) Pub. Date: Mar. 5, 2015

(54) VERTICAL CAVITY SURFACE EMITTING LASER

(71) Applicant: MURATA MANUFACTURING CO., LTD., Kyoto-fu (JP)

(72) Inventors: Keiji IWATA, Kyoto-fu (JP); Ippei MATSUBARA, Kyoto-fu (JP); Takayuki KONA, Kyoto-fu (JP); Hiroshi WATANABE, Kyoto-fu (JP); Masashi YANAGASE, Kyoto-fu (JP)

(73) Assignee: MURATA MANUFACTURING CO., LTD., Kyoto-fu (JP)

(21) Appl. No.: 14/537,995

(22) Filed: Nov. 11, 2014

Related U.S. Application Data
(63) Continuation of application No. PCT/JP2013/064301, filed on May 23, 2013.

(30) Foreign Application Priority Data
May 25, 2012 (JP) 2012-119460

(51) Int. Cl. H01S 5/183; H01S 5/34

(52) U.S. Cl. CPC H01S 5/183; H01S 5/34
USPC 372/45.01

(57) ABSTRACT

A vertical cavity surface emitting laser includes a base substrate formed by a semi-insulating semiconductor, a light-emitting region multilayer portion including an N-type semiconductor contact layer, an N-type semiconductor multilayer-film reflecting layer, an N-type semiconductor clad layer, an active layer provided with a quantum well, a P-type semiconductor clad layer, a P-type semiconductor multilayer-film reflecting layer, and a P-type semiconductor contact layer, which are formed on the surface of the base substrate sequentially, an anode electrode formed on the surface of the P-type semiconductor contact layer, and a cathode electrode that is connected to the N-type semiconductor clad layer. The cathode electrode is formed on the base substrate at the side of the light-emitting region multilayer portion. A groove is formed among respective vertical cavity surface emitting lasers.

### CROSS REFERENCE TO RELATED APPLICATIONS

This application claims benefit of priority to Japanese Patent Application 2012-119460 filed May 25, 2012, and to International Patent Application No. PCT/JP2013/064301 filed May 23, 2013, the entire content of each of which is incorporated herein by reference.

### TECHNICAL FIELD

The present technical field relates to a vertical cavity surface emitting laser including a plurality of vertical cavity surface emitting lasers.

### BACKGROUND

Currently, a vertical cavity surface emitting laser (VCSEL) has been put into practical use as one type of a semiconductor laser.

As a schematic configuration of a vertical cavity surface emitting laser, a first multilayer distributed Bragg reflector (DBR) layer is formed on an upper layer of a base substrate formed by an N-type semiconductor including a cathode electrode formed on the back surface thereof as described in Japanese Unexamined Patent Application Publication (Translation of PCT Application) No. 2003-508928, for example. A first spacer layer is formed on an upper layer of the first DBR layer. An active layer including a quantum well is formed on an upper layer of the first spacer layer. A second spacer layer is formed on an upper layer of the active layer. A second DBR layer is formed on an upper layer of the second spacer layer. An anode electrode is formed on an upper layer of the second DBR layer. A driving signal is applied between the anode electrode and the cathode electrode so as to generate laser beams having sharp directivity in the direction perpendicular to the substrate (parallel with the lamination direction).

When a plurality of vertical cavity surface emitting lasers are provided to be arrayed, for example, a configuration in which the individual vertical cavity surface emitting lasers each having the above-mentioned configuration are mounted on different circuit substrates and a configuration in which they are mounted on a common base substrate are considered.

### SUMMARY

### Technical Problem

When the above-mentioned vertical cavity surface emitting lasers formed individually are mounted on different circuit substrates, the structure is increased in size.

On the other hand, when they are mounted on a single base substrate, in the case where the base substrate is formed by the N-type semiconductor substrate and the cathode electrode is formed on the surface at the side opposite to the active layer with respect to the base substrate as described above, respective driving signals that are applied to the respective vertical cavity surface emitting lasers leak into the N-type semiconductor substrate. This causes crosstalk among the driving signals to be generated, resulting in a problem that sufficient isolation cannot be provided among the vertical cavity surface emitting lasers.

An object of the present disclosure is to provide a vertical cavity surface emitting laser capable of forming a plurality of vertical cavity surface emitting lasers on a single base substrate while ensuring isolation among the vertical cavity surface emitting lasers.

### Solution to Problem

The present disclosure provides a vertical cavity surface emitting laser including a base substrate, a light-emitting region multilayer portion including an N-type semiconductor multilayer-film reflecting layer, an active layer provided with a quantum well, and a P-type semiconductor multilayer-film reflecting layer, which are formed on a surface of the base substrate, an anode electrode connected to the P-type semiconductor multilayer-film reflecting layer, and a cathode electrode connected to the N-type semiconductor multilayer-film reflecting layer. At least a portion of a predetermined thickness of the base substrate at a side of the light-emitting region multilayer portion is formed by a semi-insulating semiconductor. The cathode electrode is formed on the base substrate at a side of the surface. A plurality of groups of light emitting element constituent components each constituted by the light-emitting region multilayer portion, the anode electrode, and the cathode electrode are formed on the base substrate. The plurality of light emitting element constituent components are isolated individually and the respective light emitting element constituent components are driven independently.

With this configuration, the base substrate is formed by the semi-insulating semiconductor and the respective light emitting element constituent components are isolated individually and are driven independently. This causes the respective light emitting element constituent components to be electrically isolated from one another even when the plurality of light emitting element constituent components are formed on a single base substrate, thereby preventing crosstalk of driving signals among them from being generated.

In the vertical cavity surface emitting laser according to one aspect of the disclosure, it is preferable that a void portion be provided among the plurality of light emitting element constituent components and the void portion have a shape recessed to an inner side portion of the base substrate from the surface of the base substrate.

With this configuration, the respective light emitting element constituent components are electrically isolated from one another more reliably.

It is preferable that the vertical cavity surface emitting laser according to one aspect of the disclosure have the following configuration. That is, an anode pad electrode which is connected to the anode electrode and a cathode pad electrode which is connected to the cathode electrode are provided for each of the light emitting element constituent components divided by the void portion. The anode pad electrode and the cathode pad electrode are formed on a surface of an insulating layer arranged on the surface of the base substrate on a region different from the light-emitting region multilayer portion, the anode electrode, and the cathode electrode.

With this configuration, the respective light emitting element constituent components are electrically isolated from one another more reliably.

It is preferable that the vertical cavity surface emitting laser according to one aspect of the disclosure have the following configuration. That is, adjacent light emitting element constituent components are arranged on the base substrate at the side of the surface such that anode pad electrodes are adjacent to each other or cathode pad electrodes are adjacent to each other.

With this configuration, electric coupling between the pad electrodes can be suppressed in the adjacent light emitting element constituent components. This enables the respective light emitting element constituent components to be electrically isolated from one another more reliably.

It is preferable that the vertical cavity surface emitting laser according to one aspect of the disclosure have the following configuration. That is, two cathode pad electrodes are provided. The two cathode pad electrodes are arranged on the surface of the insulating layer such that the anode pad electrode is interposed between the two cathode pad electrodes.

With this configuration, the cathode pad electrodes of the adjacent light emitting element constituent components are adjacent to each other necessarily. This can suppress electric coupling between the pad electrodes in the adjacent light emitting element constituent components. Therefore, the respective light emitting element constituent components are electrically isolated from one another more reliably.

In the vertical cavity surface emitting laser according to one aspect of the disclosure, it is preferable that an insulating film be formed to have a shape excluding at least a part of the anode pad electrode and the cathode pad electrode.

With this configuration, the insulating film electrically isolates the respective light emitting element constituent components more reliably.

In the vertical cavity surface emitting laser according to one aspect of the disclosure, it is preferable that the void portion have a tapered shape so that a width between adjacent light emitting element constituent components is narrower toward a side of the base substrate from a side of the anode electrode.

This configuration indicates a specific shape of the void portion. With this configuration, the void portion is easy to be formed. Further, when the insulating film is formed, the insulating film is easy to be formed.

In the vertical cavity surface emitting laser according to one aspect of the disclosure, it is preferable that the resistivity of the semi-insulating semiconductor forming the base substrate be equal to or higher than 1.0×10⁷ Ω·cm.

In the vertical cavity surface emitting laser according to one aspect of the disclosure, it is preferable that an interval between close electrodes of adjacent light emitting element constituent components be equal to or larger than 0.5 μm.

With these configurations, the respective light emitting element constituent components are electrically isolated from one another more reliably.

The vertical cavity surface emitting laser according to one aspect of the disclosure can also have the following configuration. That is, a portion of the base substrate, which has a predetermined thickness from a surface at a side of the light emitting element constituent component, is formed by the semi-insulating semiconductor. An N-type semiconductor substrate is arranged at a side opposite to the light emitting element constituent component of the semi-insulating semiconductor.

With this configuration, failure due to crystal defect caused by the base substrate can be suppressed while providing electric isolation among the above-mentioned plurality of light emitting element constituent components.

### Advantageous Effects of Disclosure

According to the present disclosure, while a plurality of vertical cavity surface emitting lasers are formed on a single base substrate, isolation among the respective vertical cavity surface emitting lasers can be ensured.

### BRIEF DESCRIPTION OF THE DRAWINGS

FIG. 1 is a partial plan view illustrating a vertical cavity surface emitting laser 1 according to a first embodiment of the disclosure.

FIG. 2 is a cross-sectional view illustrating a single vertical cavity surface emitting laser 10 constituting the vertical cavity surface emitting laser 1 according to the first embodiment of the disclosure, which is cut along a plane 2-2.

FIG. 3 is a cross-sectional view illustrating the vertical cavity surface emitting laser 1 according to the first embodiment of the disclosure, which is cut along a plane 3-3.

FIG. 4 is a cross-sectional view illustrating a region on which are formed cathode pad electrodes and anode pad electrodes of a vertical cavity surface emitting laser 1A according to a second embodiment of the disclosure.

FIG. 5 is a partial plan view illustrating a vertical cavity surface emitting laser 1B according to a third embodiment of the disclosure.

FIG. 6 is a partial plan view illustrating a vertical cavity surface emitting laser 1C according to a fourth embodiment of the disclosure.

FIG. 7 is a cross-sectional view illustrating a region on which are formed cathode pad electrodes and anode pad electrodes of the vertical cavity surface emitting laser according to the fourth embodiment of the disclosure.

FIG. 8 is a cross-sectional view illustrating a region on which are formed cathode pad electrodes and anode pad electrodes of a vertical cavity surface emitting laser according to a fifth embodiment of the disclosure.

### DETAILED DESCRIPTION

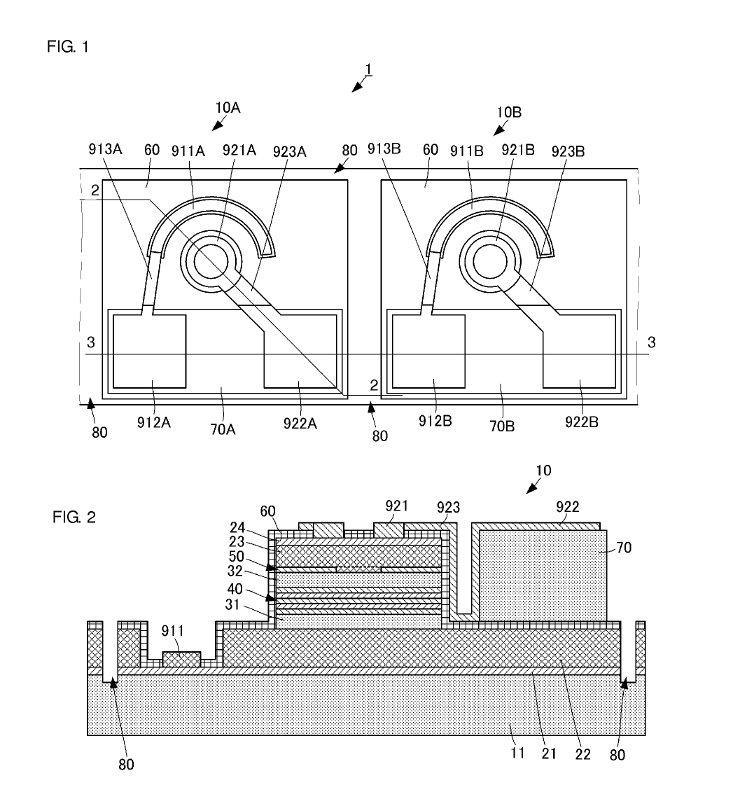

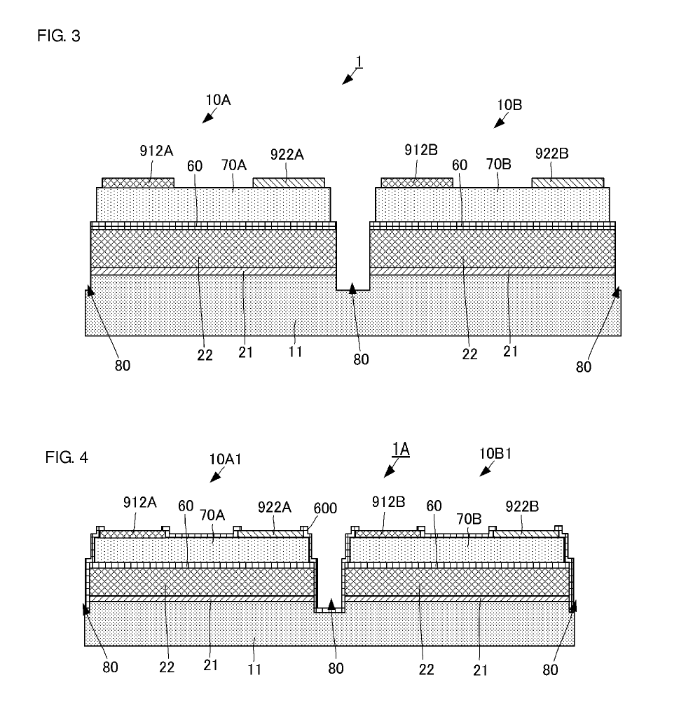

A vertical cavity surface emitting laser (VCSEL) according to a first embodiment of the disclosure is described with reference to the accompanying drawings. Hereinafter, the vertical cavity surface emitting laser is referred to as a VCSEL. FIG. 1 is a partial plan view illustrating a vertical cavity surface emitting laser 1 according to the first embodiment of the disclosure. FIG. 2 is a cross-sectional view illustrating a single vertical cavity surface emitting laser 10 constituting the vertical cavity surface emitting laser 1 according to the first embodiment of the disclosure, which is cut along a plane 2-2. FIG. 3 is a cross-sectional view illustrating the vertical cavity surface emitting laser 1 according to the first embodiment of the disclosure, which is cut along a plane 3-3. In FIG. 1 and FIG. 3, only two vertical cavity surface emitting lasers 10A and 10B are illustrated but the number of vertical cavity surface emitting lasers constituting the VCSEL 1 is not limited thereto.

The VCSEL 1 includes a plurality of vertical cavity surface emitting lasers. That is to say, the plurality of vertical cavity surface emitting lasers that are arrayed are driven independently. The plurality of vertical cavity surface emitting lasers 10A and 10B are each formed on the surface of a single base substrate 11.

The base substrate 11 is formed by a semi-insulating semiconductor. To be specific, the base substrate 11 is formed by a substrate made of GaAs as a material. The base substrate 11 preferably has resistivity of equal to or higher than 1.0×10⁷ Ω·cm. The base substrate 11 formed by the semi-insulating semiconductor having the above-mentioned resistivity is used so as to ensure isolation more highly between the vertical cavity surface emitting lasers 10A and 10B, which will be described later.

An N-type semiconductor contact layer 21 is laminated and formed on the surface of the base substrate 11. The N-type semiconductor contact layer 21 is formed by a compound semiconductor having N-type conductivity.

An N-type multilayer distributed Bragg reflector (DBR) layer 22 is laminated and formed on the surface of the N-type semiconductor contact layer 21. The N-type semiconductor DBR layer 22 is made of an AlGaAs material and formed by laminating a plurality of layers having different composition ratios of Al relative to Ga. This layer configuration forms a first reflector for generating laser beams having a predetermined frequency. The N-type semiconductor DBR layer may also serve as an N-type semiconductor contact layer. That is to say, the N-type semiconductor contact layer is not essential.

N-type semiconductor clad layers 31 are laminated and formed on the surface of the N-type semiconductor DBR layer 22 for the respective vertical cavity surface emitting lasers 10A and 10B. The N-type semiconductor clad layers 31 of the respective vertical cavity surface emitting lasers 10A and 10B are formed on the surface of the N-type semiconductor DBR layer 22 so as to be separated from each other by a predetermined distance. The N-type semiconductor clad layers 31 are also made of the AlGaAs material.

Active layers 40 are formed on the surfaces of the respective N-type semiconductor clad layers 31. The active layers 40 are made of a GaAs material and the AlGaAs material. AlGaAs layers are made to serve as optical confinement layers having a high band gap and GaAs layers are formed so as to be interposed between the AlGaAs layers. With this configuration, the active layers 40 are formed as layers each having a single or a plurality of quantum wells interposed between the optical confinement layers having a high band gap.

P-type semiconductor clad layers 32 are formed on the surfaces of the respective active layers 40. The P-type semiconductor clad layers 32 are also made of the AlGaAs material.

P-type semiconductor DBR layers 23 are formed on the surfaces of the P-type semiconductor clad layers 32. The P-type semiconductor DBR layers 23 are made of the AlGaAs material and are formed by laminating a plurality of layers having different composition ratios of Al relative to Ga. The layer configuration forms a second reflector for generating laser beams having a predetermined frequency. The P-type semiconductor DBR layers 23 are formed to have the reflectivity slightly lower than that of the N-type semiconductor DBR layers 31. Although the semiconductor clad layers are formed with the active layers interposed therebetween, the configuration is not limited thereto. Layers having such film thicknesses that they generate resonance may be provided with the active layers.

Oxidization constriction layers 50 are formed on the boundary surfaces between the P-type semiconductor clad layers 32 and the P-type semiconductor DBR layers 23. The oxidization constriction layers 50 are made of the AlGaAs material and have a composition ratio of Al relative to Ga, which is set to be higher than those of other layers. The oxidization constriction layers 50 are not entirely formed on the overall boundary surfaces between the P-type semiconductor clad layers and the P-type semiconductor DBR layers 23 and non-formation portions thereof are present at substantially the center of formation regions so as to have predetermined areas.

P-type semiconductor contact layers 24 are laminated and formed on the surfaces of the P-type semiconductor DBR layers 23. The P-type semiconductor contact layers 24 are formed by a compound semiconductor having P-type conductivity. The P-type semiconductor DBR layers may also serve as the P-type semiconductor contact layers. That is to say, the P-type semiconductor contact layers are not essential.

The N-type semiconductor contact layer 21, the N-type semiconductor DBR layer 22, the N-type semiconductor clad layer 31, the active layer 40, the P-type semiconductor clad layer 32, the P-type semiconductor DBR layer 23, and the P-type semiconductor contact layer 24 constitute a “light-emitting region multilayer portion” according to the disclosure.

In this configuration, the thicknesses of the respective layers and the composition ratios of Al relative to Ga are set such that a plurality of quantum wells having one light-emitting spectrum peak wavelength at a valley position at the center of an optical standing wave distribution are arranged. This causes the respective light-emitting region multilayer portions to function as light emitting portions of the vertical cavity surface emitting lasers. Further, the above-mentioned oxidization constriction layers 50 are provided so as to inject an electric current to active regions efficiently and obtain a lens effect. This can provide the vertical cavity surface emitting laser with reduced power consumption.

Anode electrodes 921 (921A and 921B) are formed on the surfaces of the P-type contact layers 24. The anode electrodes 921 (921A and 921B) are ring-like electrodes when seen from above as illustrated in FIG. 1. It should be noted that the anode electrodes are not necessarily formed into ring shapes. For example, the anode electrodes may be formed into rectangular shapes or C shapes where a part of each of the ring shapes is opened.

Regions on which the N-type semiconductor DBR layer 22 is not formed are provided on the surface of the N-type semiconductor contact layer 21 for the respective vertical cavity surface emitting lasers 10A and 10B. These regions are formed in the vicinity of regions of the N-type semiconductor DBR layer 22 on which the N-type semiconductor clad layers 31 are laminated and formed.

Cathode electrodes 911 (911A and 911B) are formed on these regions for the respective vertical cavity surface emitting lasers 10A and 10B. The cathode electrodes 911 (911A and 911B) are formed so as to conduct with the N-type semiconductor contact layer 21. The cathode electrodes 911 (911A and 911B) are circular arc-like electrodes when seen from above as illustrated in FIG. 1.

Insulating films 60 are formed at the surface side of the base substrate 11 so as not to cover at least a part of the cathode electrodes 911 (911A and 911B) and the anode electrodes 921 (921A and 921B) while covering the outer surfaces of the respective other constituent components constituting the light-emitting region multilayer portions. The insulating films 60 are made of silicon nitride (SiNx) as a material, for example.

Insulating layers 70 are laminated and formed on the surfaces of the insulating films 60 in the vicinity of regions of the N-type semiconductor DBR layer 22 on which the N-type semiconductor clad layers 31 are formed. The insulating layers 70 are made of polyimide as a material, for example.

Cathode pad electrodes 912 (912A and 912B) and anode pad electrodes 922 (922A and 922B) are formed on the surfaces of the insulating layers 70 so as to be separated from each other. An insulating layer 70A is formed in the vicinity of the light-emitting region multilayer portion of the vertical cavity surface emitting laser 10A. The cathode pad electrode 912A and the anode pad electrode 922A are formed on the surface of the insulating layer 70A so as to be separated from each other. An insulating layer 70B is formed in the vicinity of the light-emitting region multilayer portion of the vertical cavity surface emitting laser 10B. The cathode pad electrode 912B and the anode pad electrode 922B are formed on the surface of the insulating layer 70B so as to be separated from each other.

The cathode pad electrode 912A is connected to the cathode electrode 911A through a cathode wiring electrode 913A. The cathode pad electrode 912B is connected to the cathode electrode 911B through a cathode wiring electrode 913B.

The anode pad electrode 922A is connected to the anode electrode 921A through an anode wiring electrode 923A. The anode pad electrode 922B is connected to the anode electrode 921B through an anode wiring electrode 923B.

In the configuration in the embodiment, as illustrated in FIG. 2 and FIG. 3, a groove 80 is formed so as to have a shape penetrating through the insulating films 60, the N-type semiconductor DBR layer 22, and the N-type semiconductor contact layer 21 in the lamination direction and recessed from the surface of the base substrate 11 by a predetermined depth. The groove 80 is formed to have such shape that the light-emitting region multilayer portions and the electrodes forming the anodes and cathodes connected to the light-emitting region multilayer portions, which constitute the respective vertical cavity surface emitting lasers 10A and 10B, are isolated into the respective vertical cavity surface emitting lasers 10A and 10B. The groove 80 and spaces with which the respective light-emitting region multilayer portions and the anodes and cathodes, which constitute the respective vertical cavity surface emitting lasers 10A and 10B, are separated from each other with the predetermined distances therebetween constitute a “void portion” according to the disclosure.

With this configuration, the respective vertical cavity surface emitting lasers 10A and 10B are isolated individually. That is to say, even when driving signals are applied between the anodes and the cathodes of the vertical cavity surface emitting lasers 10A and 10B, the void portion and the base substrate 11 formed by the semi-insulating semiconductor suppress leakage of the driving signals between the adjacent light-emitting region multilayer portions. With this, even when the VCSEL 1 in which the vertical cavity surface emitting lasers 10A and 10B are configured to be arrayed on the single base substrate 11 is formed, isolation between the adjacent vertical cavity surface emitting lasers can be highly ensured. Accordingly, crosstalk due to the driving signals between the adjacent vertical cavity surface emitting lasers can be suppressed, thereby providing high speed modulation driving of the respective vertical cavity surface emitting lasers.

In this case, the plurality of vertical cavity surface emitting lasers that are arrayed are formed on the single base substrate 11, so that the configuration of the VCSEL array is simplified so as to achieve size reduction. In addition, the isolation between the adjacent vertical cavity surface emitting lasers can be highly ensured as described above, thereby shortening a distance between the adjacent vertical cavity surface emitting lasers 10. For example, an experiment result made by an inventor revealed that the distance between the adjacent vertical cavity surface emitting lasers 10 can be made approximately half of that in the existing technique. This can reduce the VCSEL 1 in size.

The above-mentioned action effect can be obtained by forming the base substrate 11 by the semi-insulating semiconductor as described above. In addition, the isolation between the adjacent vertical cavity surface emitting lasers can be more highly ensured by providing the above-mentioned groove 80.

Moreover, as described above, the insulating layers 70 are provided so as to separate the cathode pad electrodes 912 and the anode pad electrodes 922 of the respective vertical cavity surface emitting lasers from the N-type semiconductor DBR layer 22. With this, the isolation between the adjacent vertical cavity surface emitting lasers can be more highly ensured.

The vertical cavity surface emitting laser 1 having the above-mentioned configuration is manufactured as follows, for example. Although a formation example of a single vertical cavity surface emitting laser will be mainly described below, the plurality of vertical cavity surface emitting lasers that are formed on the surface of the base substrate 11 are formed by the same process at the same time.

First, the N-type semiconductor contact layer 21, the N-type semiconductor DBR layer 22, the N-type semiconductor clad layers 31, the active layers 40, the P-type semiconductor clad layers 32, the P-type semiconductor DBR layers 23, and the P-type semiconductor contact layers 24 as described above are laminated and formed on the surface of the base substrate 11 in this order.

Then, the P-type semiconductor contact layers 24, the P-type semiconductor DBR layers 23, the P-type semiconductor clad layers 32, the active layers 40, and the N-type semiconductor clad layers 31 excluding portions thereof constituting the light-emitting region multilayer portions of the respective vertical cavity surface emitting lasers 10A and 10B are sequentially etched with predetermined patterns. The etching is performed on the surface of the N-type semiconductor DBR layer 22 in the regions that are etched. With this, the light-emitting region multilayer portions of the respective vertical cavity surface emitting lasers 10A and 10B other than the N-type semiconductor contact layer 21 and the N-type semiconductor DBR layer 22 are isolated so as to be separated from each other by the predetermined distance.

Regions in which the surface of the N-type semiconductor DBR layer 22 is exposed at positions close to the light-emitting region multilayer portions are etched so as to expose the N-type semiconductor contact layer 21. The cathode electrodes 911 are formed on the regions in which the N-type semiconductor contact layer 21 is exposed.

The anode electrodes 921 are formed on the surfaces of the P-type contact layers 24 on the light-emitting region multilayer portions that have not been etched.

The insulating films 60 are formed at the surface side of the base substrate 11 excluding the surfaces of the cathode electrodes 911 and the anode electrodes 921.

The insulating layers 70 are formed on the surfaces of the insulating films 60 on regions close to the light-emitting region multilayer portions.

The cathode pad electrodes 912 and the anode pad electrodes 922 are formed on the surfaces of the insulating layers 70.

The cathode wiring electrodes 913 connecting the cathode electrodes 911 and the cathode pad electrodes 912 are formed. The anode wiring electrodes 923 connecting the anode electrodes 921 and the anode pad electrodes 912 are formed.

The groove 80 having the shape penetrating through the insulating films 60, the N-type semiconductor DBR layer 22, and the N-type semiconductor contact layer 21 and recessed to the inner portions of the base substrate 11 from the surface thereof by the predetermined depth is formed so as to divide the regions of the adjacent vertical cavity surface emitting lasers.

The VCSEL 1 is formed by the above-mentioned manufacturing processes. It is preferable for the width of the void portion that is generated between the vertical cavity surface emitting lasers is gradually made larger toward the side of the P-type contact layers 24 and smaller toward the side of the N-type contact layer 21 by the etching. That is to say, the void is preferably tapered. This configuration can improve the covering property of the insulating layers 60 on the side surfaces of the light-emitting region multilayer portions and ensure the isolation between the light-emitting region multilayer portions more highly.

The following describes a vertical cavity surface emitting laser (VCSEL) according to a second embodiment of the disclosure with reference to the drawing. FIG. 4 is a cross-sectional view illustrating regions on which cathode pad electrodes and anode pad electrodes are formed on a vertical cavity surface emitting laser 1A according to the second embodiment of the disclosure.

The VCSEL 1A in the embodiment is configured by adding an insulating film 600 to the VCSEL 1 as described in the first embodiment. Other configurations thereof are the same as those of the VCSEL 1 as described in the first embodiment. Accordingly, only different portions are described.

The insulating film 600 is made of silicon nitride or the like that is the same as the material of the insulating films 60 in the first embodiment. The insulating film 600 has a shape covering the surface of the base surface 11 at the side of the light-emitting region multilayer portions, which includes the inner surfaces of the groove 80. Note that the insulating layer 600 is not formed on the surfaces of the cathode pad electrodes and the anode pad electrodes in a range enabling them to be connected to external elements by wire bonding or the like.

With this configuration, the surfaces (inner surfaces of the groove 80) of the N-type semiconductor contact layer 21 and the N-type semiconductor DBR layer 22 opposing each other with the groove 80 therebetween are also covered by the insulating layer 600. This can ensure a higher isolation between vertical cavity surface emitting lasers 10A1 and 10B1 which are adjacent to each other with the groove 80 therebetween.

The following describes a vertical cavity surface emitting laser (VCSEL) according to a third embodiment with reference to the drawing. FIG. 5 is a partial plan view illustrating a vertical cavity surface emitting laser 1B according to the third embodiment of the disclosure.

The VCSEL 1B in one embodiment has arrangement patterns of cathode pad electrodes and anode pad electrodes of respective vertical cavity surface emitting lasers 10A2 and 10B2, which are different from those of the VCSEL 1 as described in the first embodiment. Other configurations thereof are the same as those of the VCSEL 1 as described in the first embodiment. Accordingly, only different portions are described.

The VCSEL 1B is arranged such that pad electrodes of the same poles are adjacent between the vertical cavity surface emitting lasers 10A2 and 10B2, adjacent to each other with the groove 80 therebetween so as to be parallel with the alignment direction of the cathode pad electrodes and the anode pad electrodes. As a specific example, as illustrated in FIG. 5, the VCSEL 1B is arranged such that an anode pad electrode 922A of the vertical cavity surface emitting laser 10A2 and an anode pad electrode 922B of the vertical cavity surface emitting laser 10B2 are adjacent. Although not illustrated in the drawing, a vertical cavity surface emitting laser which is arranged at the side opposite to the vertical cavity surface emitting laser 10B2 with respect to the vertical cavity surface emitting laser 10A2 is arranged such that a cathode pad electrode thereof is adjacent to that of the vertical cavity surface emitting laser 10A2. In the same manner, although not illustrated in the drawing, a vertical cavity surface emitting laser which is arranged at the side opposite to the vertical cavity surface emitting laser 10A2 with respect to the vertical cavity surface emitting laser 10B2 is arranged such that a cathode pad electrode thereof is adjacent to that of the vertical cavity surface emitting laser 10B2.

Thus, the pad electrodes of the same poles of the adjacent vertical cavity surface emitting lasers are made adjacent to each other, thereby further suppressing crosstalk due to the driving signals to the respective vertical cavity surface emitting lasers.

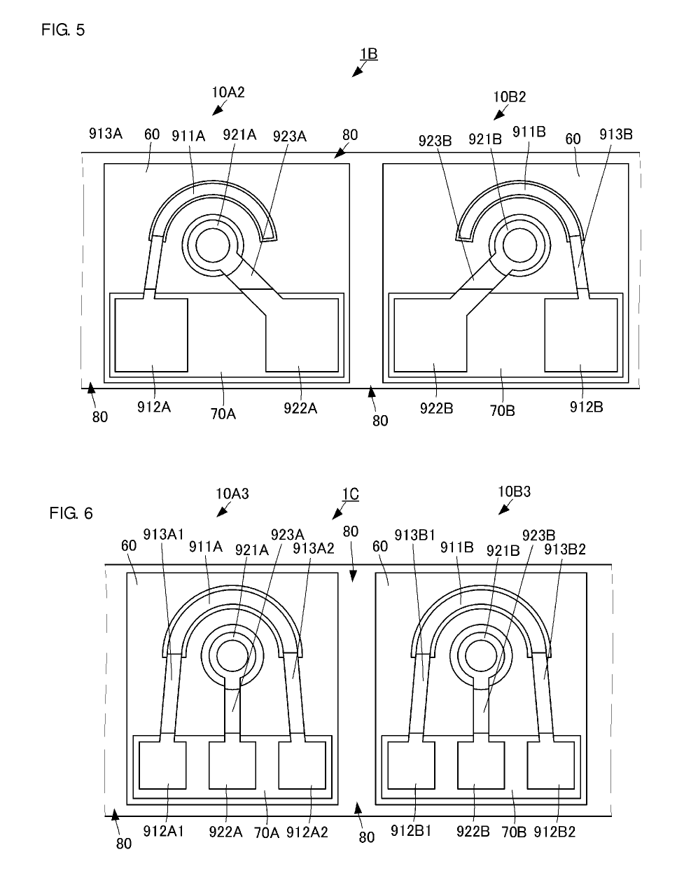

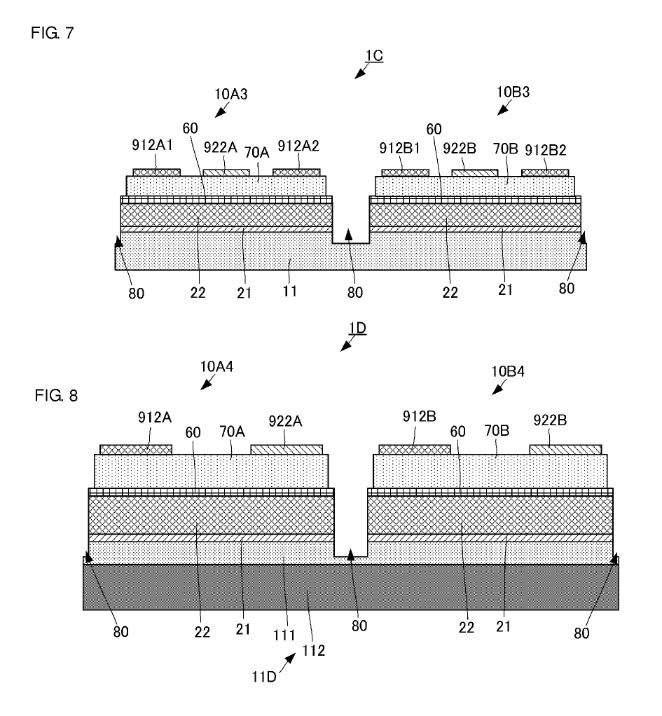

The following describes a vertical cavity surface emitting laser (VCSEL) according to a fourth embodiment with reference to the drawings. FIG. 6 is a partial plan view illustrating a vertical cavity surface emitting laser 1C according to the fourth embodiment of the disclosure. FIG. 7 is a cross-sectional view illustrating regions on which cathode pad electrodes and anode pad electrodes are formed on the vertical cavity surface emitting laser according to the fourth embodiment of the disclosure.

The VCSEL 1C in one embodiment is different from the VCSEL 1 as described in the first embodiment in a point that two cathode pad electrodes are provided for respective vertical cavity surface emitting lasers 10A3 and 10B3. Other configurations thereof are the same as those of the VCSEL 1 as described in the first embodiment. Accordingly, only different portions are described.

Two cathode pad electrodes 912A1 and 912A2 are formed on the vertical cavity surface emitting laser 10A3. The cathode pad electrodes 912A1 and 912A2 are connected to the cathode electrode 911A through cathode wiring electrodes 913A1 and 913A2. The cathode pad electrodes 912A1 and 912A2 are arranged on the surface of the insulating layer 70 such that the anode pad electrode 922A is interposed therebetween so as to be parallel with the direction in which the vertical cavity surface emitting lasers are aligned.

Two cathode pad electrodes 912B1 and 912B2 are formed on the vertical cavity surface emitting laser 10B3. The cathode pad electrodes 912B1 and 912B2 are connected to the cathode electrode 911B through cathode wiring electrode 913B1 and 913B2. The cathode pad electrodes 912B1 and 912B2 are arranged on the surface of the insulating layer 70 such that the anode pad electrode 922B is interposed therebetween so as to be parallel with the direction in which the vertical cavity surface emitting lasers are aligned.

With this configuration, the adjacent vertical cavity surface emitting lasers 10A3 and 10B3 are arranged such that the cathode pad electrodes of the same poles are made adjacent to each other. This can further suppress crosstalk due to the driving signals to the respective vertical cavity surface emitting lasers as in the third embodiment.

The following describes a vertical cavity surface emitting laser (VCSEL) according to a fifth embodiment with reference to the drawing. FIG. 8 is a cross-sectional view illustrating regions on which cathode pad electrodes and anode pad electrodes are formed on the vertical cavity surface emitting laser in the fifth embodiment of the disclosure.

A VCSEL 1D in one embodiment is different from the VCSEL 1 as described in the first embodiment in the configuration of a base substrate 11D. Other configurations thereof are the same as those of the VCSEL 1 as described in the first embodiment. Accordingly, only different places are described.

The base substrate 11D includes a semi-insulating semiconductor layer 111 and a conductive semiconductor layer 112 formed by an N-type semiconductor.

Regions of the base substrate 11D at the surface side on which the light-emitting region multilayer portions are formed, which have a predetermined thickness, are formed by the semi-insulating semiconductor layer 111. The conductive semiconductor layer 112 is formed on the surface of the semi-insulating semiconductor layer 111 at the side opposite to the surface on which the light-emitting region multilayer portions are formed. The thickness of the semi-insulating semiconductor 111 is smaller than the thickness of the conductive semiconductor layer 112.

The groove 80 is formed to have a shape recessed in at least the semi-insulating semiconductor layer 111 by a predetermined depth. It should be noted that the groove 80 may have a depth reaching the conductive semiconductor layer 112.

Even this configuration can also provide effects the same as those obtained in the above-mentioned respective embodiments. Further, an N-type semiconductor layer is provided at a part of the base substrate 11D, thereby largely reducing generation of a crystal defect. This can form a VCSEL with higher reliably.

Although the insulating layers 70 are provided in the above-mentioned respective embodiments, they can be omitted. It should be noted that the insulating layers 70 are provided so as to suppress parasitic capacity to be generated on the cathode pad electrodes and the anode pad electrodes. This can suppress generation of crosstalk between the adjacent vertical cavity surface emitting lasers more effectively.

Further, although examples of specific numeral values are not indicated in the above-mentioned respective embodiments, it is preferable that an interval between the respective anode electrodes and the respective cathode electrodes adjacent to each other be equal to or larger than 0.5 μm. The conditions are satisfied so as to suppress generation of the above-mentioned crosstalk effectively.

1. A vertical cavity surface emitting laser comprising:
a base substrate;
a light-emitting region multilayer portion including an N-type semiconductor multilayer-film reflecting layer, an active layer provided with a quantum well, and a P-type semiconductor multilayer-film reflecting layer, which are formed on a surface of the base substrate;
an anode electrode connected to the P-type semiconductor multilayer-film reflecting layer, and
a cathode electrode connected to the N-type semiconductor multilayer-film reflecting layer,
at least a portion of a predetermined thickness of the base substrate at a side of the light-emitting region multilayer portion being formed by a semi-insulating semiconductor,
the cathode electrode being formed on the base substrate at a side of the surface,
a plurality of groups of light emitting element constituent components each constituted by the light-emitting region multilayer portion, the anode electrode, and the cathode electrode being formed on the base substrate, and
the plurality of light emitting element constituent components being isolated individually and the plurality of light emitting element constituent components being driven independently.

2. The vertical cavity surface emitting laser according to claim 1,
wherein a void portion is provided among the plurality of light emitting element constituent components and the void portion has a shape recessed to an inner side portion of the base substrate from the surface of the base substrate.

3. The vertical cavity surface emitting laser according to claim 2, wherein an anode pad electrode which is connected to the anode electrode and a cathode pad electrode which is connected to the cathode electrode are provided for each of the light emitting element constituent components divided by the void portion, and
the anode pad electrode and the cathode pad electrode are formed on a surface of an insulating layer arranged on the surface of the base substrate on a region different from the light-emitting region multilayer portion, the anode electrode, and the cathode electrode.

4. The vertical cavity surface emitting laser according to claim 3,
wherein adjacent light emitting element constituent components are arranged on the base substrate at the side of the surface such that anode pad electrodes are adjacent to each other or cathode pad electrodes are adjacent to each other.

5. The vertical cavity surface emitting laser according to claim 3,
wherein two cathode pad electrodes are provided, and
the two cathode pad electrodes are arranged on the surface of the insulating layer such that the anode pad electrode is interposed between the two cathode pad electrodes.

6. The vertical cavity surface emitting laser according to claim 3,
wherein an insulating film is formed to have a shape excluding at least a part of the anode pad electrode and the cathode pad electrode.

7. The vertical cavity surface emitting laser according to claim 2,
wherein the void portion has a tapered shape so that a width between adjacent light emitting element constituent components is narrower toward a side of the base substrate from a side of the anode electrode.

8. The vertical cavity surface emitting laser according to claim 1,
wherein a resistivity of the semi-insulating semiconductor forming the base substrate is equal to or higher than 1.0×10⁷ Ω·cm.

9. The vertical cavity surface emitting laser according to claim 1,
wherein an interval between close electrodes of adjacent light emitting element constituent components is equal to or larger than 0.5 μm.

10. The vertical cavity surface emitting laser according to claim 1,
wherein a portion of the base substrate, which has a predetermined thickness from a surface at a side of the light emitting element constituent components, is formed by the semi-insulating semiconductor, and
an N-type semiconductor substrate is arranged on the semi-insulating semiconductor at a side opposite to the light emitting element constituent components.
